(19) United States
(12) Patent Application Publication
(10) Pub. No.: US 2012/0000531 A1
(43) Pub. Date: Jan. 5, 2012

(54) CIGS Solar Cell and Method for Manufacturing thereof

(75) Inventor: Yan-Way LI, TAICHUNG COUNTY (TW)

(73) Assignee: GCSOL TECH CO., LTD., Taichung County (TW)

(21) Appl. No.: 12/901,585

(22) Filed: Oct. 11, 2010

(30) Foreign Application Priority Data
Jul. 2, 2010 (TW) 99121861

(51) Int. Cl. H01L 31/0272; H01L 31/18

(52) U.S. Cl. 136/262; 438/95; 257/E31.027

(57) ABSTRACT

A CIGS solar cell includes a glass substrate, a light absorbing surface and a photoelectric transducer structure. The glass substrate includes a plurality of arrayed protrusions. The arrayed protrusions protrude from at least one surface of the glass substrate, wherein the depth from the top of the arrayed protrusions to the bottom of the arrayed protrusions is predetermined. The light absorbing surface is located on the top of the arrayed protrusions, the side of the arrayed protrusions and the surface of the glass substrate between the arrayed protrusions. The photoelectric transducer structure includes an n-type semiconductor layer, an i-type semiconductor layer and a p-type semiconductor layer.

### RELATED APPLICATIONS

The application claims priority to Taiwan Application Serial Number 99121861, filed Jul. 2, 2010, which is herein incorporated by reference.

### BACKGROUND

1. Technical Field

The present disclosure relates to CIGS (Copper Indium Gallium Selenide) solar cells.

2. Description of Related Art

Solar energy is one example of a renewable energy source. It can be transformed into heat and electricity, and applied to the generator or consumer electronics. But, the most important problem of the solar cell is “how to increase the efficiency of the solar cell to transform the light energy into electricity”. Therefore, the target of the solar cell industry is to increase the efficiency of the solar cell and decrease the cost.

### SUMMARY

A CIGS solar cell includes a glass substrate, a light absorbing surface and a photoelectric transducer structure. The glass substrate includes a plurality of arrayed protrusions. The arrayed protrusions protrude from at least one surface of the glass substrate, wherein the depth from the top of the arrayed protrusions to the bottom of the arrayed protrusions is predetermined. The light absorbing surface is located on the top of the arrayed protrusions, the side of the arrayed protrusions and the surface of the glass substrate between the arrayed protrusions. The photoelectric transducer structure includes an n-type semiconductor layer, an i-type semiconductor layer and a p-type semiconductor layer. The n-type semiconductor layer is located on the light absorbing surface and made of a CIGS compound. The i-type semiconductor layer is located on the n-type semiconductor layer and made of an oxide. The p-type semiconductor layer is located on the i-type semiconductor layer and made of an oxide.

A method for manufacturing a CIGS solar cell includes: A glass substrate is provided. A plurality of arrayed protrusions are formed on at least one surface of the glass substrate and a light absorbing surface is formed on the top of the arrayed protrusions, the side of the arrayed protrusions and the surface of the glass substrate between the arrayed protrusions. A bottom electrode layer is deposited onto the light absorbing surface. An intermediate layer is deposited onto the bottom electrode layer. A photoelectric transducer structure is deposited onto the intermediate layer, wherein the photoelectric transducer structure comprises an n-type semiconductor layer, an i-type semiconductor layer and a p-type semiconductor layer. A top electrode layer is deposited onto the photoelectric transducer structure. A wire is formed on the top electrode layer. An anti-reflection layer is deposited onto the wire.

### BRIEF DESCRIPTION OF THE DRAWINGS

FIG. 1 is a cross-sectional view of a CIGS solar cell according to one embodiment;

FIG. 2A is a vertical view of the glass substrate of FIG. 1;

FIG. 2B is a cross-sectional view of the glass substrate of FIG. 2A;

FIG. 3 is an enlarged view of the circle M of FIG. 1;

FIG. 4 is an enlarged cross-sectional view of a part of a CIGS solar cell according to another embodiment;

FIG. 5 is an enlarged cross-sectional view of a part of a CIGS solar cell according to yet another embodiment;

FIG. 6 is a flowchart of a method for manufacturing the CIGS solar cell according to further another embodiment;

FIG. 7 is a diagram of Step 320 of FIG. 6; and

FIG. 8 illustrates the I-V chart of the CIGS solar cell that manufactured by the method of FIG. 6.

### DETAILED DESCRIPTION

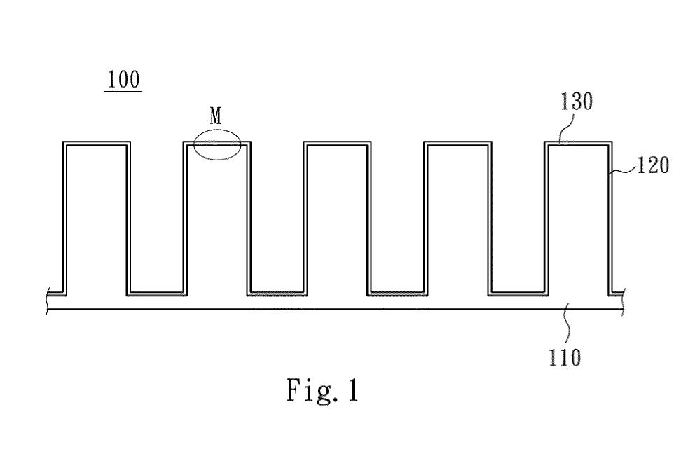

FIG. 1 is a cross-sectional view of a CIGS solar cell 100 according to one embodiment. The CIGS solar cell 100 includes a glass substrate 110, a light absorbing surface 120 and a photoelectric transducer structure 130. The light absorbing surface 120 is located on the glass substrate 110. The photoelectric transducer structure 130 is located on the light absorbing surface 120.

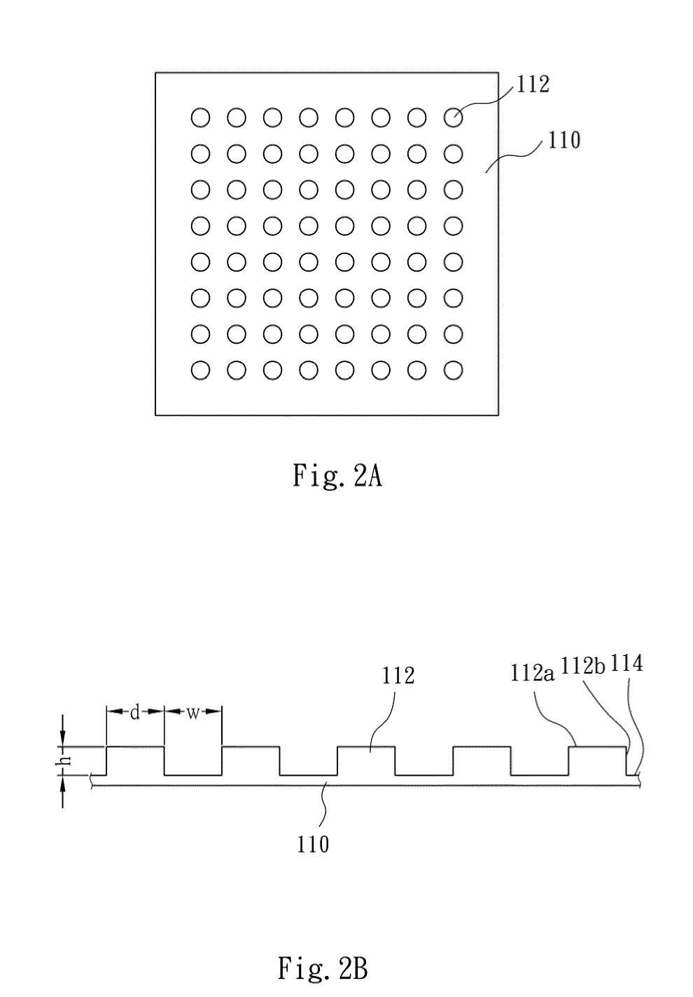

FIG. 2A is a vertical view of the glass substrate 110 of FIG. 1. FIG. 2B is a cross-sectional view of the glass substrate 110 of FIG. 2A. The glass substrate 110 includes a plurality of arrayed protrusions 112. The arrayed protrusions 112 protrude from at least one surface of the glass substrate 110. The depth h from the top of the arrayed protrusions 112 to the bottom of the arrayed protrusions 112 is predetermined. The range of the predetermined depth h is greater than or equal to 1 millimeter, especially 2 millimeter. The arrayed protrusions 112 are equally spaced at W, especially at 0.625 millimeter. The arrayed protrusions 112 are pillar-shaped, especially cylinders. The widths d of the arrayed protrusions 112 are equal. In other words, the arrayed protrusions 112 located on the surface of glass substrate 110 evenly.

The light absorbing surface 120 is located on the top 112a of the arrayed protrusions 112, the side 112b of the arrayed protrusions 112 and the surface 114 of the glass substrate 110 between the arrayed protrusions 112. Therefore, the surface for absorbing light is increased by the formation of the arrayed protrusions 112.

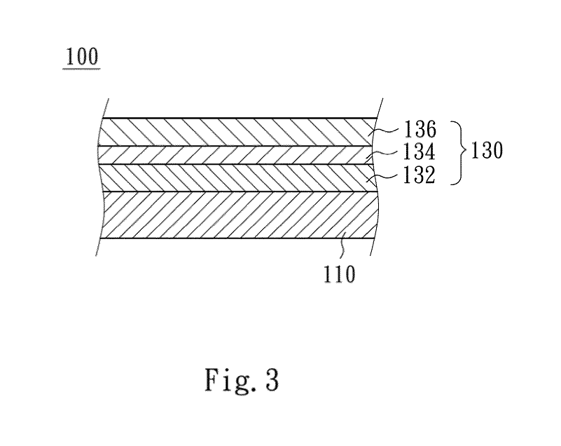

FIG. 3 is an enlarged view of the circle M of FIG. 1. The photoelectric transducer structure 130 includes an n-type semiconductor layer 132, an i-type semiconductor layer 134 and a p-type semiconductor layer 136. The n-type semiconductor layer 132 is located on the light absorbing surface 120 and made of a CIGS compound. The chemical formula of the CIGS compound is Sn:Cu(In₁₋ₓGaₓ)Se₂, wherein x is 0.18-0.3. Furthermore, the CIGS compound includes a first precursor compound and a second precursor compound. The first precursor compound includes Copper (Cu), Gallium (Ga) and Selenium (Se), such as Cu—Ga—Se alloy. The second precursor compound includes Indium (In) and Selenium (Se), such as In—Se alloy. The i-type semiconductor layer 134 is located on the n-type semiconductor layer 132 and made of an oxide. The p-type semiconductor layer 136 is located on the i-type semiconductor layer 134 and made of an oxide. The p-type semiconductor layer 136 includes copper oxide and aluminum oxide.

In an example of the CIGS solar cell 100, the thickness of the CIGS compound is 1500 nm-2500 nm and the band-gap energy is 1.17 eV. The i-type semiconductor layer 134 is made of Cu₂O. The thickness of the i-type semiconductor layer 134 is 5 nm-50 nm and the band-gap energy is 2.1 eV. The p-type semiconductor layer 136 is made of CuAlO₂. The thickness of the p-type semiconductor layer 136 is 30 nm-120 nm and the band-gap energy is 3.5 eV. Therefore, the n-type semiconductor layer 132, the i-type semiconductor layer 134 and the p-type semiconductor layer 136 can absorb the different wavelength of the light.

There is a big difference between the band-gap energy of the n-type semiconductor layer 132 and the band-gap energy of the p-type semiconductor layer 136. Therefore, the n-type semiconductor layer 132 connects the p-type semiconductor layer 136 via the i-type semiconductor layer 134. The oxide of the i-type semiconductor layer 134 can decrease the carrier recombination from the p-type semiconductor layer 136 and the n-type semiconductor layer 132 and increase the quantum efficiency.

### Increase Ratio of the Area of the Light Absorbing Surface

The efficiency of the light absorption is referred to the area of the light absorbing surface. In other words, the external surface of the glass substrate 110 (includes the top 112a and the side 112b of the arrayed protrusions 112 and the surface 114 of the glass substrate 110 between the arrayed protrusions 112) is greater, the efficiency of the light absorption is greater. In the external surface of the glass substrate 110, the increase ratio of the area of the light absorbing surface 120 with various widths and spaces between the arrayed protrusions are shown in Table 1 as following.

TABLE 1

| | | | | | | Increase ratio of |
|---|---|---|---|---|---|---|
| | The arrayed protrusions | | | | The light | the area of the |
| | Width | Space | Depth | | absorbing surface | light absorbing |
| | (cm) | (cm) | (cm) | Quantity | (cm2) | surface |
| Comparison | 0 | 0 | 0 | 0 | 100 | — |
| Example 1 | | | | | | |
| Example 1 | 0.5 | 0.5 | 0.2 | 64 | 120.1 | 20% |
| Example 2 | 0.25 | 0.25 | 0.2 | 256 | 140.2 | 40% |
| Example 3 | 0.125 | 0.125 | 0.2 | 1024 | 180.4 | 80% |
| Example 4 | 0.0625 | 0.0625 | 0.2 | 4096 | 260.8 | 160% |

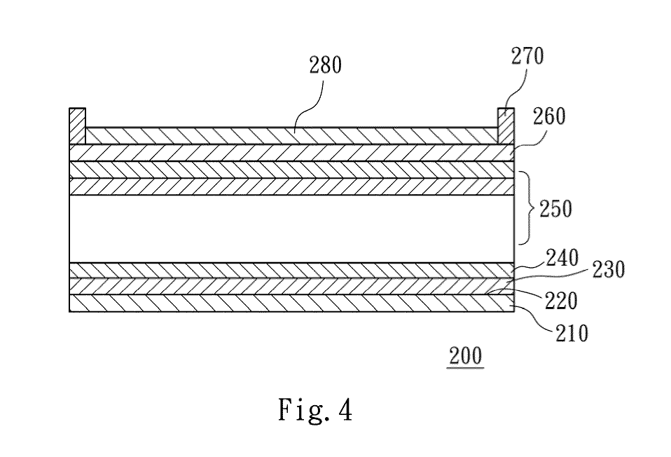

FIG. 4 is an enlarged cross-sectional view of a part of a CIGS solar cell 200 according to another embodiment. The CIGS solar cell 200 includes a glass substrate 210, a light absorbing surface 220, a bottom electrode layer 230, an intermediate layer 240, a photoelectric transducer structure 250, a top electrode layer 260, a wire 270 and an anti-reflection layer 280. The structure of the glass substrate 210, the light absorbing surface 220 and the photoelectric transducer structure 250 are equal to the CIGS solar cell 100 in FIG. 1. Thus, the following description is only for the difference between FIG. 1.

The bottom electrode layer 230 is located between the glass substrate 210 and the photoelectric transducer structure 250. The bottom electrode layer 230 is made of a metal. The metal is Titanium (Ti), Molybdenum (Mo), Tantalum (Ta) or an alloy thereof, especially Mo.

The intermediate layer 240 is located between the photoelectric transducer structure 250 and the bottom electrode layer 230. The intermediate layer 240 is made of Stannum (Sn), Tellurium (Te) or Plumbum (Pb), especially Sn.

In an example of FIG. 4, the thickness of the intermediate layer 240 is 5 nm-50 nm. The intermediate layer 240 is made of the metal, so that the sodium (Na) of the glass substrate 210 can diffuse through the bottom electrode layer 230 by thermal diffusion. Therefore, the intermediate layer 240 can wet around the surface of the bottom electrode layer 230 during heating and thus improve the interface smoothness between the bottom electrode layer 230 and the photoelectric transducer structure 250.

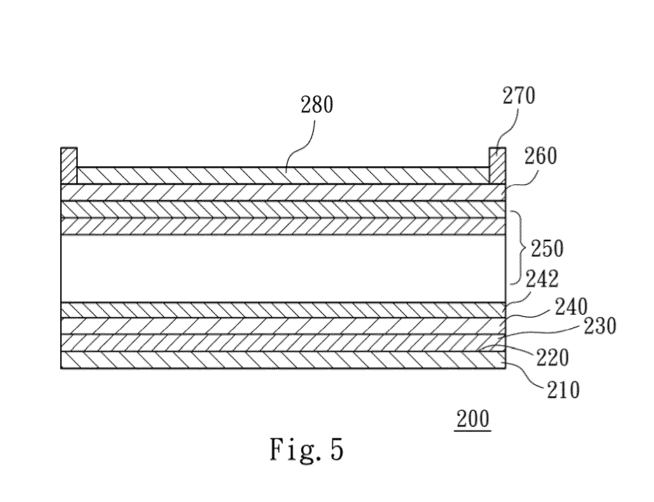

FIG. 5 is an enlarged cross-sectional view of a part of a CIGS solar cell 200 according to yet another embodiment. In FIG. 5, the bottom electrode layer 230 is made of a nonmetallic oxide, such as Indium Tin Oxide (ITO). The Oxide interfere the diffusion of Na. Therefore, the CIGS solar cell 200 further includes a sodium-compound layer 242, such as sodium fluoride (NaF). The sodium-compound layer 242 is used to supply Na atoms for enhancing CIGS grain growth during heating and located between the bottom electrode layer 230 and the photoelectric transducer structure 250. Thus, the absorber can absorb the incident light from the front and the back direction through the transparent ITO bottom electrode layer 230 enhancing. The light efficiency can be more promoted by the design.

The top electrode layer 260 is located on the photoelectric transducer structure 250. In an example of FIG. 5, the top electrode layer 260 is made of Aluminum doped zinc oxide (AZO, ZnO:Al). The wire 270 is located on the top of electrode layer 260. The anti-reflection layer 280 is located on the wire 270. The anti-reflection layer 280 is made of silicon nitride (Si₃N₄:H) and the thickness of the anti-reflection layer 280 is 80 nm-150 nm.

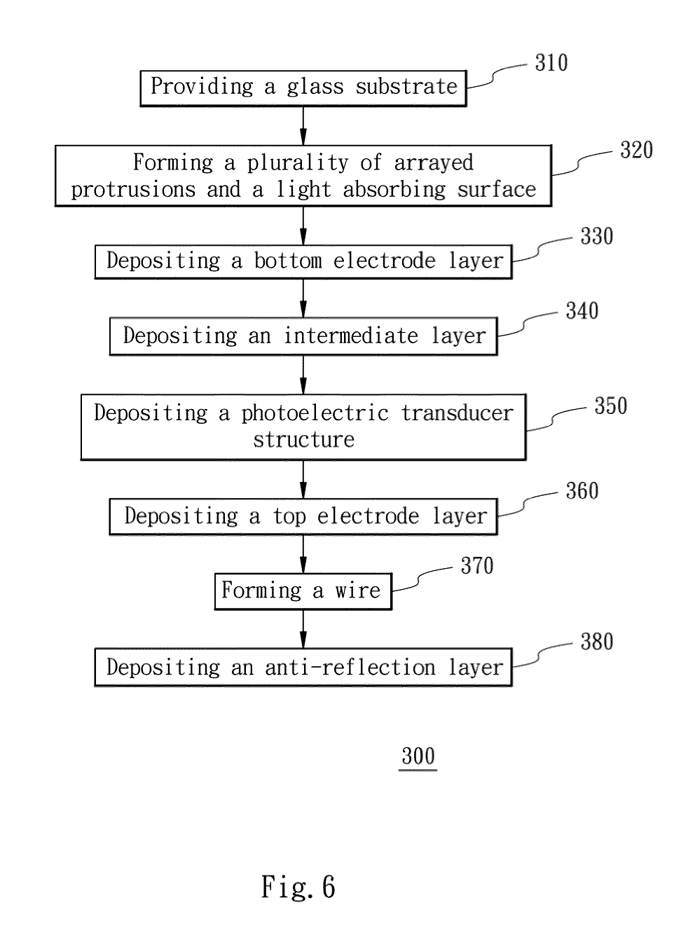

FIG. 6 is a flowchart of a method for manufacturing the CIGS solar cell according to further another embodiment. The method 300 includes the steps:

Step 310: Providing a glass substrate;

Step 320: Forming a plurality of arrayed protrusions on at least one surface of the glass substrate and forming a light absorbing surface on the top of the arrayed protrusions, the side of the arrayed protrusions and the surface of the glass substrate between the arrayed protrusions;

Step 330: Depositing a bottom electrode layer onto the light absorbing surface;

Step 340: Depositing an intermediate layer onto the bottom electrode layer;

Step 350: Depositing a photoelectric transducer structure onto the intermediate layer, wherein the photoelectric transducer structure comprises an n-type semiconductor layer, an i-type semiconductor layer and a p-type semiconductor layer;

Step 360: Depositing a top electrode layer onto the photoelectric transducer structure;

Step 370: Forming a wire on the top electrode layer; and

Step 380: Depositing an anti-reflection layer onto the wire.

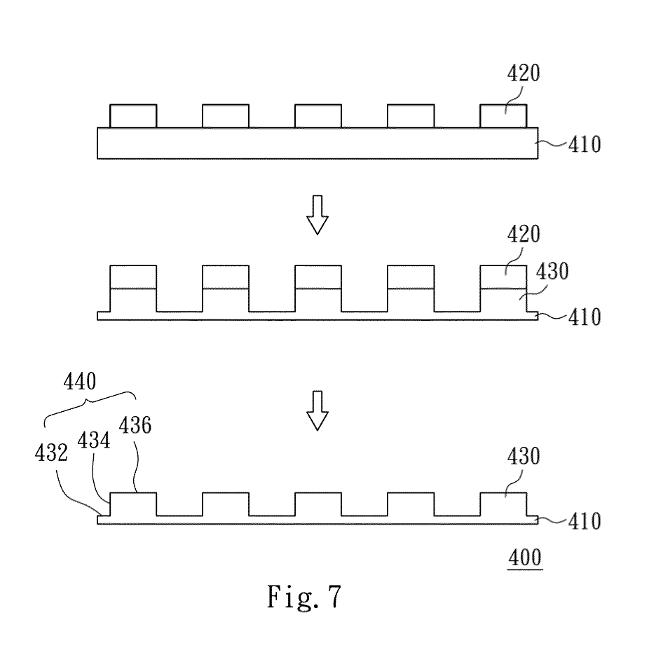

FIG. 7 is a diagram of Step 320 of FIG. 6. First, the surface of the glass substrate 410 is coated with a protective film 420. The protective film 420 is a paraffin wax. Second, the glass substrate 410 is soaked in an etchant, such as hydrofluoric acid solution. The glass substrate 410 is etched and formed the arrayed protrusions 430. The time of soaking is longer, the depth from the top of the arrayed protrusions 430 to the bottom of the arrayed protrusions 430 is greater. In an example of FIG. 7, the depth from the top of the arrayed protrusions 430 to the bottom of the arrayed protrusions 430 is greater than or equal to 1 millimeter. After a predetermined time for etching, the glass substrate 410 can be taken out and rinsed. Third, the protective film 420 is removed from the glass substrate 410. Therefore, the top 436 of the arrayed protrusions 430, the side 434 of the arrayed protrusions 430 and the surface 432 of the glass substrate 410 between the arrayed protrusions 430 are the light absorbing surface 440.

The bottom electrode layer is deposited onto the light absorbing surface 440. The bottom electrode layer can be made of a metal or a nonmetallic oxide. The metal is Titanium (Ti), Molybdenum (Mo), Tantalum (Ta) or an alloy thereof. The intermediate layer is deposited onto the bottom electrode layer. The intermediate layer is made of Stannum (Sn), Tellurium (Te) or Plumbum (Pb). The photoelectric transducer structure is deposited onto the intermediate layer wherein the photoelectric transducer structure comprises an n-type semiconductor layer, an i-type semiconductor layer and a p-type semiconductor layer in order.

Especially, when the bottom electrode layer is made of the nonmetallic oxide, a sodium-compound layer is formed between the bottom electrode layer and the photoelectric transducer structure.

In Step 350, the n-type semiconductor layer is formed into a CIGS compound, such as Sn:Cu(In₁₋ₓGaₓ)Se₂, wherein x is 0.18-0.3. In detail, the n-type semiconductor layer is formed by heating the intermediate layer and the first precursor compound film and the second precursor compound film in a VIA Group gas atmosphere. The element of the intermediate layer is diffuse into the CIGS compound as a dopant during heating and then the CIGS compound is formed into an n-type semiconductor layer. The first precursor compound comprises Copper (Cu), Gallium (Ga) and Selenium (Se). The second precursor compound comprises Indium (In) and Selenium (Se). The thickness of the n-type semiconductor layer is 1500 nm-2500 nm.

The first precursor compound film and the second precursor compound film are formed by electro-deposition, electroless-deposition, atomic layer deposition, chemical vapor deposition, metal-organic chemical vapor deposition or physical vapor deposition. The VIA Group gas is activated by an excitation source during the aforementioned heating, wherein the excitation source is activated by an electron beam device, an ion beam device, a plasma resonance device or a pyrolysis device. The temperature of heating the first precursor film and the second precursor film is 380° C.-600° C.

Cuprous oxide in this invention is set to be an i-type semiconductor film, a copper film is deposited on the surface of the n-type semiconductor by atomic layer deposition and then by thermal oxidation at 180° C. to form cuprous oxide phase. The p-type semiconductor layer is deposited onto the i-type semiconductor layer. The p-type semiconductor layer includes copper oxide and aluminum oxide.

The top electrode layer, the wire and the anti-reflection layer are formed on the photoelectric transducer structure in order. The top electrode layer and the anti-reflection layer are formed by sputter deposition.

The example 4 of Table 1, the glass substrate is coated with a plurality of circle paraffin wax, wherein the diameter of the circles is 0.0625 cm. The circles are equally spaced at 0.0625 cm. When the paraffin wax becomes solid, the glass substrate can be soaked in the hydrofluoric acid solution and be etched. After 30 minutes-40 minutes, the arrayed protrusions protrudes from the surface of the glass substrate at about 2 millimeter. The increase ratio of the area of the light absorbing surface is about 160%.

The bottom is formed on the arrayed protrusions at 1 μm by sputter deposition. The intermediate layer (tin film), CuGaSe film and InSe film are deposited on the bottom, and heated thereof. The heating process includes two heating steps for the reactions. First heating step is heating under the selenium vapor at 400° C. Second heating step is heating under the selenium vapor and sulfur vapor at 580° C. Thus, the CIGS layer with a sulfurized surface is formed at about 2000 nm. The value of Cu/(In+Ga) is 0.85-0.90 and the value of Ga/(In+Ga) is about 0.25.

The copper film is deposited at 180° C. by atomic layer deposition. In other words, the copper film is oxidized at 180° C., so that the copper film becomes the cuprous oxide film at 30 nm. At the time, the CuAlO₂ and AZO is deposited.

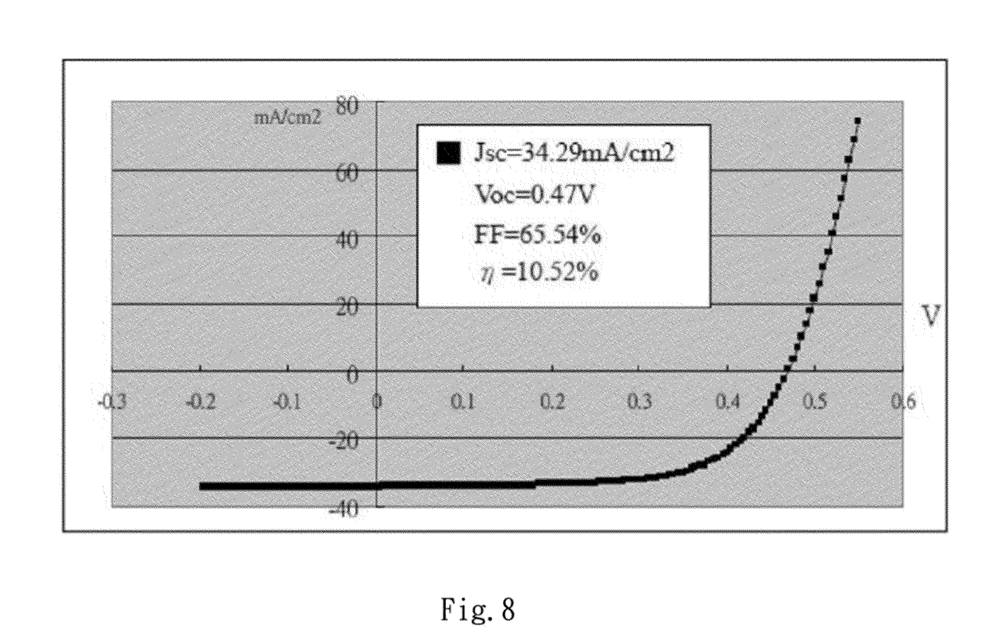

FIG. 8 illustrates the I-V chart of the CIGS solar cell that manufactured by the method of FIG. 6. After finish the steps of FIG. 6, the CIGS solar cell is tested by the light (100 mW/cm², AM1.5). The open circuit voltage is 0.47 V. The fill factor (FF) is 64.54%. The efficiency of the CIGS solar cell is 10.52%.

Therefore, there are some advantages according to the present embodiments as following:

1. A plurality of the arrayed protrusions on the surface of the solar cell can increase the absorption of the light and the photoelectric yield.

2. The intermediate layer can improve the junction between the photoelectric transducer structure and the bottom electrode layer. In other words, the intermediate layer can improve the smoothness between the photoelectric transducer structure and the bottom electrode layer.

3. The i-type semiconductor layer is made of the oxide. Thus, the i-type semiconductor layer can improve the junction of the p-type semiconductor layer and the n-type semiconductor layer, and the quantum efficiency of the photoelectric transducer structure can be increased.

What is claimed is:

1. A CIGS solar cell comprising:
a glass substrate comprising a plurality of arrayed protrusions, wherein the arrayed protrusions protrude from at least one surface of the glass substrate, wherein the depth from the top of the arrayed protrusions to the bottom of the arrayed protrusions is predetermined;
a light absorbing surface located on the top of the arrayed protrusions, the side of the arrayed protrusions and the surface of the glass substrate between the arrayed protrusions; and
a photoelectric transducer structure comprising:
an n-type semiconductor layer located on the light absorbing surface and made of a CIGS compound;
an i-type semiconductor layer located on the n-type semiconductor layer and made of an oxide; and
a p-type semiconductor layer located on the i-type semiconductor layer and made of an oxide.

2. The CIGS solar cell of claim 1, further comprising:
a bottom electrode layer located between the glass substrate and the photoelectric transducer structure, wherein the bottom electrode layer is made of a metal.

3. The CIGS solar cell of claim 2, wherein the metal is Titanium (Ti), Molybdenum (Mo), Tantalum (Ta) or an alloy thereof.

4. The CIGS solar cell of claim 2, further comprising:
an intermediate layer located between the photoelectric transducer structure and the bottom electrode layer.

5. The CIGS solar cell of claim 4, wherein the intermediate layer is made of Stannum (Sn), Tellurium (Te) or Plumbum (Pb).

6. The CIGS solar cell of claim 1, further comprising:
a bottom electrode layer located between the glass substrate and the photoelectric transducer structure, wherein the bottom electrode layer is made of a nonmetallic oxide; and
a sodium-compound layer located between the bottom electrode layer and the photoelectric transducer structure.

7. The CIGS solar cell of claim 1, further comprising:
a top electrode layer located on the photoelectric transducer structure.

8. The CIGS solar cell of claim 7, further comprising:
a wire located on the top electrode layer.

9. The CIGS solar cell of claim 8, further comprising:
an anti-reflection layer located on the wire.

10. The CIGS solar cell of claim 1, wherein the predetermined depth is greater than or equal to 1 millimeter.

11. The CIGS solar cell of claim 1, wherein the CIGS compound comprises a first precursor compound and a second precursor compound.

12. The CIGS solar cell of claim 11, wherein the first precursor compound comprises Copper (Cu), Gallium (Ga) and Selenium (Se).

13. The CIGS solar cell of claim 11, wherein the second precursor compound comprises Indium (In) and Selenium (Se).

14. The CIGS solar cell of claim 1, wherein the chemical formula of the CIGS compound is Sn:Cu(In₁₋ₓGaₓ)Se₂, wherein x is 0.18-0.3.

15. The CIGS solar cell of claim 1, wherein the p-type semiconductor layer comprises copper oxide and aluminum oxide.

16. The CIGS solar cell of claim 1, wherein the arrayed protrusions are equally spaced.

17. The CIGS solar cell of claim 16, wherein the arrayed protrusions are equally spaced at 0.625 millimeter.

18. The CIGS solar cell of claim 1, wherein the arrayed protrusions are pillar-shaped.

19. The CIGS solar cell of claim 18, wherein the arrayed protrusions are cylinders.

20. A method for manufacturing a CIGS solar cell, the method comprising:
providing a glass substrate;
forming a plurality of arrayed protrusions on at least one surface of the glass substrate and forming a light absorbing surface on the top of the arrayed protrusions, the side of the arrayed protrusions and the surface of the glass substrate between the arrayed protrusions;
depositing a bottom electrode layer onto the light absorbing surface;
depositing an intermediate layer onto the bottom electrode layer;
depositing a photoelectric transducer structure onto the intermediate layer, wherein the photoelectric transducer structure comprises an n-type semiconductor layer, an i-type semiconductor layer and a p-type semiconductor layer;
depositing a top electrode layer onto the photoelectric transducer structure;
forming a wire on the top electrode layer; and
depositing an anti-reflection layer onto the wire.

21. The method for manufacturing the CIGS solar cell of claim 20, wherein forming the arrayed protrusions comprises:
coating a protective film onto the surface of the glass substrate;
soaking the glass substrate in an etchant, taking out the glass substrate after a predetermined time, and then rinsing the glass substrate; and
removing the protective film from the glass substrate.

22. The method for manufacturing the CIGS solar cell of claim 20, wherein the depth from the top of the arrayed protrusions to the bottom of the arrayed protrusions is greater than or equal to 1 millimeter.

23. The method for manufacturing the CIGS solar cell of claim 20, wherein the bottom electrode layer is made of a metal.

24. The method for manufacturing the CIGS solar cell of claim 23, wherein the metal is Titanium (Ti), Molybdenum (Mo), Tantalum (Ta) or an alloy thereof.

25. The method for manufacturing the CIGS solar cell of claim 20, further comprising:
forming a sodium-compound layer between the bottom electrode layer and the photoelectric transducer structure, wherein the bottom electrode layer is made of a nonmetallic oxide.

26. The method for manufacturing the CIGS solar cell of claim 20, wherein the intermediate layer is made of Stannum (Sn), Tellurium (Te) or Plumbum (Pb).

27. The method for manufacturing the CIGS solar cell of claim 20, wherein the n-type semiconductor layer is formed by heating a first precursor compound film and a second precursor compound film in a VIA Group gas atmosphere.

28. The method for manufacturing the CIGS solar cell of claim 27, wherein the first precursor compound film comprises Copper (Cu), Gallium (Ga) and Selenium (Se).

29. The method for manufacturing the CIGS solar cell of claim 27, wherein the second precursor compound film comprises Indium (In) and Selenium (Se).

30. The method for manufacturing the CIGS solar cell of claim 27, wherein the first precursor compound film and the second precursor compound film are formed by electro-deposition, electroless-deposition, atomic layer deposition, chemical vapor deposition, metal-organic chemical vapor deposition or physical vapor deposition.

31. The method for manufacturing the CIGS solar cell of claim 27, wherein heating the first precursor compound film and the second precursor compound film comprises:
activating an excitation source for activating the VIA Group gas, wherein the excitation source is activated by an electron beam device, an ion beam device, a plasma resonance device or a pyrolysis device.

32. The method for manufacturing the CIGS solar cell of claim 27, wherein the temperature of heating the first precursor compound film and the second precursor compound film is 380° C.-600° C.

33. The method for manufacturing the CIGS solar cell of claim 20, wherein the n-type semiconductor layer comprises Sn:Cu(In₁₋ₓGaₓ)Se₂, wherein x is 0.18-0.3.

34. The method for manufacturing the CIGS solar cell of claim 20, wherein the p-type semiconductor layer comprises copper oxide and aluminum oxide.

35. The method for manufacturing the CIGS solar cell of claim 20, wherein the arrayed protrusions are equally spaced.

36. The method for manufacturing the CIGS solar cell of claim 20, wherein the arrayed protrusions are pillar-shaped.
